(19) United States
(12) Patent Application Publication
(10) Pub. No.: US 2026/0169055 A1
(43) Pub. Date: Jun. 18, 2026

(54) METHOD OF INSPECTING DISPLAY PANEL AND METHOD OF MANUFACTURING ELECTRONIC DEVICE

(71) Applicant: SAMSUNG DISPLAY CO., LTD., YONGIN-SI (KR)

(72) Inventors: SEOKGI BAEK, Yongin-si (KR); KI-HOON LEE, Yongin-si (KR); DUHYUN KIM, Yongin-si (KR); TAE-JIN JANG, Yongin-si (KR)

(21) Appl. No.: 19/312,453

(22) Filed: Aug. 28, 2025

(30) Foreign Application Priority Data
Dec. 12, 2024 (KR) 10-2024-0185087

(51) Int. Cl. G01R 31/28

(52) U.S. Cl. CPC G01R 31/2825

(57) ABSTRACT

An inspecting method of a display panel includes testing a pixel circuit including a first capacitor connected between a first node and a second node, a first transistor including a first electrode connected to a third node, a gate electrode connected to the first node, and a second electrode connected to the second node, and a second transistor connected between the first node and a data line. The testing of the pixel circuit includes applying a first test voltage to the first node, forming a current path between the third node and the second node, and measuring a current flowing through the first node via the data line.

### CROSS-REFERENCE TO RELATED APPLICATION(S)

This U.S. patent application claims priority under 35 U.S.C. § 119 to Korean Patent Application No. 10-2024-0185087, filed on Dec. 12, 2024 in the Korean Intellectual Property Office, the disclosure of which is incorporated by reference in its entirety herein.

### 1. TECHNICAL FIELD

The present disclosure is directed to a method of inspecting a display panel and a method of manufacturing an electronic device.

### 2. DISCUSSION OF RELATED ART

Various types of light emitting display devices have been developed to meet increasing demands for high-resolution, high-efficiency, and flexible display technologies. These include organic light emitting diode (OLED) displays, inorganic light emitting displays, hybrid organic-inorganic light emitting displays, quantum dot displays, micro-light emitting diode (micro-LED) displays, and nano-light emitting diode (nano-LED) displays. OLED and hybrid displays are known for their excellent color reproduction and thin form factor, making them well-suited for mobile and wearable devices. Inorganic and micro-LED displays offer high brightness, durability, and energy efficiency, making them attractive for larger-scale applications such as televisions and digital signage. Quantum dot and nano-LED displays leverage quantum confinement effects to achieve superior color purity and brightness.

A display panel of these display devices typically includes pixels and driving circuits. For example, the driving circuits may include a scan driving circuit, a data driving circuit, and an emission driving circuit, to control the pixels. Each of the pixels includes a light emitting element and a pixel circuit to control the light emitting element. The pixel circuit includes transistors connected to each other. A driving current supplied to the light emitting element is controlled by the transistors. Accordingly, if the transistors malfunction or if the wirings connecting transistors become open or short-circuited, the driving current may not be properly supplied to the light emitting element.

A test circuit may be used to test such defects. For example, the test circuit may perform a test method after the light emitting elements have been formed. However, such a test method may fail to isolate electrical defects in the pixel circuit itself, and detecting defects at this late stage results in increased manufacturing waste and cost.

### SUMMARY

The present disclosure provides a method for testing a pixel circuit included in a display panel.

The present disclosure also provides a method of manufacturing an electronic device that includes testing the pixel circuit to determine whether it functions properly prior to proceeding with subsequent fabrication steps.

An embodiment of the inventive concept provides a method of inspecting a display panel. The method includes testing a pixel circuit including a first capacitor connected between a first node and a second node, a first transistor including a first electrode connected to a third node, a gate electrode connected to the first node, and a second electrode connected to the second node, and a second transistor connected between the first node and a data line. The testing of the pixel circuit includes applying a first test voltage to the first node, forming a current path between the third node and the second node, and measuring a current flowing through the first node via the data line.

A voltage at the first node may be coupled to the second node by the first capacitor in the forming of the current path.

The measuring of the current may include turning on the second transistor and measuring the current flowing through the first node coupled to the second node.

The measuring of the current may further include applying a bias voltage to the data line after the second transistor is turned on.

The forming of the current path may include applying a second test voltage to the second node and applying a third test voltage different from the second test voltage to the third node.

A voltage level of the second test voltage may be lower than a voltage level of the third test voltage.

The pixel circuit further may include a third transistor connected between a first voltage line and the first node, a fourth transistor connected between a second voltage line and a fourth node, and a fifth transistor connected between a third voltage line and the third node. The first voltage line may transmit the first test voltage, the second voltage line may transmit the second test voltage and the third voltage line may transmit the third test voltage.

In an embodiment, the third transistor is turned on in the applying of the first test voltage, and the second transistor, the fourth transistor, and the fifth transistor are turned off in the applying of the first test voltage.

In an embodiment, the fourth transistor is turned on in the applying of the second test voltage, and the second transistor and the third transistor are turned off in the applying of the second test voltage.

In an embodiment, the fifth transistor is turned on in the applying of the third test voltage, and the second transistor and the third transistor are turned off in the applying of the third test voltage.

In an embodiment, the pixel circuit further includes a sixth transistor connected between the second node and the fourth node, the fourth transistor and the sixth transistor are turned on in the applying of the second test voltage, and the second transistor and the third transistor are turned off in the applying of the second test voltage.

The pixel circuit may further include a second capacitor connected between the third voltage line providing the third test voltage and a back gate electrode of the first transistor.

The back gate electrode of the first transistor may be connected to the second node.

A voltage level of the first test voltage may vary.

An embodiment of the inventive concept provides a method of manufacturing an electronic device. The method includes forming a pixel circuit including a plurality of transistors and a plurality of capacitors, testing the pixel circuit, and forming a light emitting element connected to the pixel circuit. The pixel circuit includes a first capacitor connected between a first node and a second node, a first transistor including a first electrode connected to a third node, a gate electrode connected to the first node, a second electrode connected to the second node, and a back gate electrode, a second transistor connected between the first node and a data line, a third transistor connected between a first voltage line and the first node, a fourth transistor connected between a second voltage line and a fourth node, a fifth transistor connected between a third voltage line and the third node, a sixth transistor connected between the second node and the fourth node, and a second capacitor connected between the third voltage line and the back gate electrode of the first transistor. The testing of the pixel circuit includes applying a first test voltage to the first node, forming a current path between the third node and the second node, and measuring a current flowing through the first node via the data line.

A voltage at the first node may be coupled to the second node by the first capacitor in the forming of the current path.

The measuring of the current may include turning on the second transistor, applying a bias voltage to the data line, and measuring the current flowing through the first node coupled to the second node.

The forming of the current path may include applying a second test voltage to the second node and applying a third test voltage different from the second test voltage to the third node, and a voltage level of the second test voltage is lower than a voltage level of the third test voltage.

In an embodiment, the third transistor is turned on in the applying of the first test voltage and the second transistor, the fourth transistor, and the fifth transistor are turned off in the applying of the first test voltage, the fourth transistor and the sixth transistor are turned on in the applying of the second test voltage, the second transistor and the third transistor are turned off in the applying of the second test voltage, the fifth transistor is turned on in the applying of the third test voltage, and the second transistor and the third transistor are turned off in the applying of the third test voltage.

A voltage level of the first test voltage may vary.

According to an embodiment, a method of manufacturing a display panel is provided. The method includes: forming a pixel circuit to have a first transistor with a gate electrode connected to a first node, a first electrode connected to a third node, and a second electrode connected to a second node; a first capacitor connected between the first node and the second node; and a second transistor connected between the first node and a data line. The method further includes: applying a first test voltage to the first node; applying a second test voltage to the second node; applying a third test voltage, different from the second test voltage, to the third node, to form a current path through the first transistor; turning on the second transistor and applying a bias voltage to the data line; measuring a current flowing from the first node through the second transistor to the data line; and forming a light emitting element electrically connected to the pixel circuit when the measured current indicates the pixel circuit is functioning normally.

According to the above, multiple test voltages may be applied to the pixel circuit to test the pixel circuit. When it is determined that the pixel circuit is defective through the test, the pixel circuit may undergo a repair process, or when it is determined that repair is not possible, the manufacturing process of the display panel may be terminated without proceeding to a next process. When it is determined that the pixel circuit is functioning normally through the test, the light emitting element may be formed through subsequent processes. The waste of manufacturing time and cost for the display panel may be reduced through the test of the pixel circuit.

### BRIEF DESCRIPTION OF THE DRAWINGS

FIG. 1 is a perspective view of an electronic device according to an embodiment of the present disclosure;

FIG. 2 is a block diagram of an electronic device according to an embodiment of the present disclosure;

FIG. 3 is a block diagram of an electronic device according to an embodiment of the present disclosure;

FIG. 4 is an equivalent circuit diagram of a pixel according to an embodiment of the present disclosure;

FIG. 5 is a timing diagram illustrating an operation of a pixel circuit according to an embodiment of the present disclosure;

FIG. 6 is a circuit diagram illustrating an operation of testing a pixel circuit according to an embodiment of the present disclosure;

FIG. 7 is a timing diagram illustrating an operation of testing a pixel circuit according to an embodiment of the present disclosure;

FIG. 8 is a view illustrating an operation of testing a pixel circuit in a first period shown in FIG. 7;

FIG. 9A is a view illustrating an operation of testing a pixel circuit in a second period shown in FIG. 7;

FIG. 9B is a view illustrating an operation of testing a pixel circuit in a second period shown in FIG. 7;

FIG. 10 is a view illustrating an operation of testing a pixel circuit in a third period shown in FIG. 7; and

FIG. 11 is a block diagram schematically illustrating a measuring equipment used for testing according to an embodiment of the present disclosure.

### DETAILED DESCRIPTION

In the present disclosure, it will be understood that when an element (or area, layer, or portion) is referred to as being “on”, “connected to” or “coupled to” another element or layer, it can be directly on, connected or coupled to the other element or layer or intervening elements or layers may be present. Like numerals refer to like elements throughout. As used herein, the term “and/or” may include any and all combinations of one or more of the associated listed items.

It will be understood that, although the terms first, second, etc. may be used herein to describe various elements, these elements should not be limited by these terms. These terms are only used to distinguish one element from another element. Thus, a first element discussed below could be termed a second element without departing from the teachings of the present disclosure. As used herein, the singular forms, “a”, “an” and “the” are intended to include the plural forms as well, unless the context clearly indicates otherwise.

Spatially relative terms, such as “below”, “lower”, “above”, “upper” and the like, may be used herein for ease of description to describe one element or feature's relationship to another elements or features as shown in the figures.

It will be further understood that the terms “include” and/or “including”, when used in this specification, specify the presence of stated features, integers, steps, operations, elements, and/or components, but do not preclude the presence or addition of one or more other features, integers, steps, operations, elements, components, and/or groups thereof.

The term “part” or “unit” as used herein is intended to mean a software component or a hardware component that performs a specific function. The hardware component may include, for example, a field-programmable gate array (FPGA) or an application-specific integrated circuit (ASIC). The software component may refer to an executable code and/or data used by the executable code in an addressable storage medium. Thus, the software components may be, for example, object-oriented software components, class components, and task components, and may include processes, functions, attributes, procedures, subroutines, segments of program code, drivers, firmware, micro codes, circuits, data, a database, data structures, tables, arrays, or variables.

Hereinafter, embodiments of the present disclosure will be described with reference to accompanying drawings.

At least one embodiment of the disclosure provides a method for testing a pixel circuit in a display panel before forming a light emitting element, by sequentially applying multiple test voltages to the pixel circuit, forming a controlled current path, and measuring current via a data line. Based on the test results, defective pixel circuits can be repaired or excluded from further processing. This enables early detection of defects, thereby reducing unnecessary manufacturing steps and minimizing wasted time and cost in display panel production.

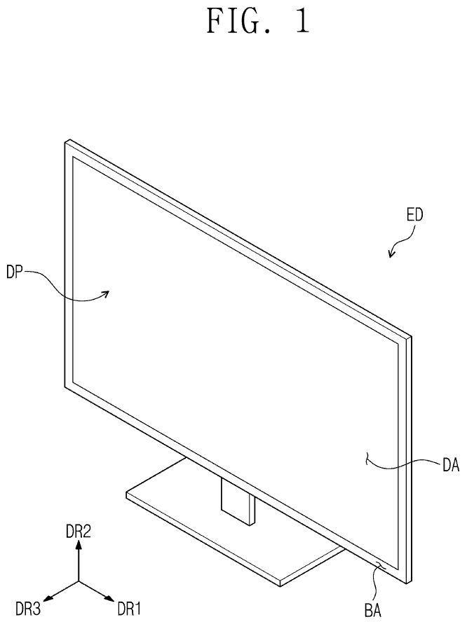

FIG. 1 is a perspective view of an electronic device ED according to an embodiment of the present disclosure.

Referring to FIG. 1, the electronic device ED may be activated in response to electrical signals. The electronic device ED may be applied to a large-sized electronic device, such as a television set, a monitor, an outdoor billboard, etc., and a small and medium-sized electronic device, such as a personal computer, a notebook computer, a personal digital terminal, a car navigation unit, a game unit, a mobile electronic device, a camera, etc. However, these are merely examples, and the electronic device ED may be applied to other display devices as long as they do not depart from the concept of the present disclosure. The electronic device ED shown in FIG. 1 may be the monitor.

The electronic device ED may include a display panel DP, which may be configured to generate and display images. The display panel DP may be a light emitting type display panel, and as an example, the display panel DP may be an organic light emitting display panel, an inorganic light emitting display panel, an organic-inorganic light emitting display panel, a quantum dot display panel, a micro-LED display panel, or a nano-LED display panel, but the present disclosure is not limited thereto. The display panel DP may be small or medium-sized, with a diagonal measurement ranging from a few inches up to a dozen inches. According to an embodiment, the display panel DP may be large-sized, measuring tens of inches or more.

The display panel DP may include a display area DA and a non-display area. The display panel DP may display images through the display area DA. As an example, the display panel DP may include a plurality of pixels, and the pixels may be arranged in the display area DA. The display area DA may include a surface defined by a first direction DR1 and a second direction DR2. The display area DA may display the images through a third direction DR3 intersecting the first direction DR1 and the second direction DR2.

A bezel area BA of the electronic device ED may cover at least a portion of the non-display area of the display panel DP. The bezel area BA may cover the entire non-display area or may cover a portion of the non-display area. When a size of the non-display area is reduced, a size of the bezel area BA may also be reduced.

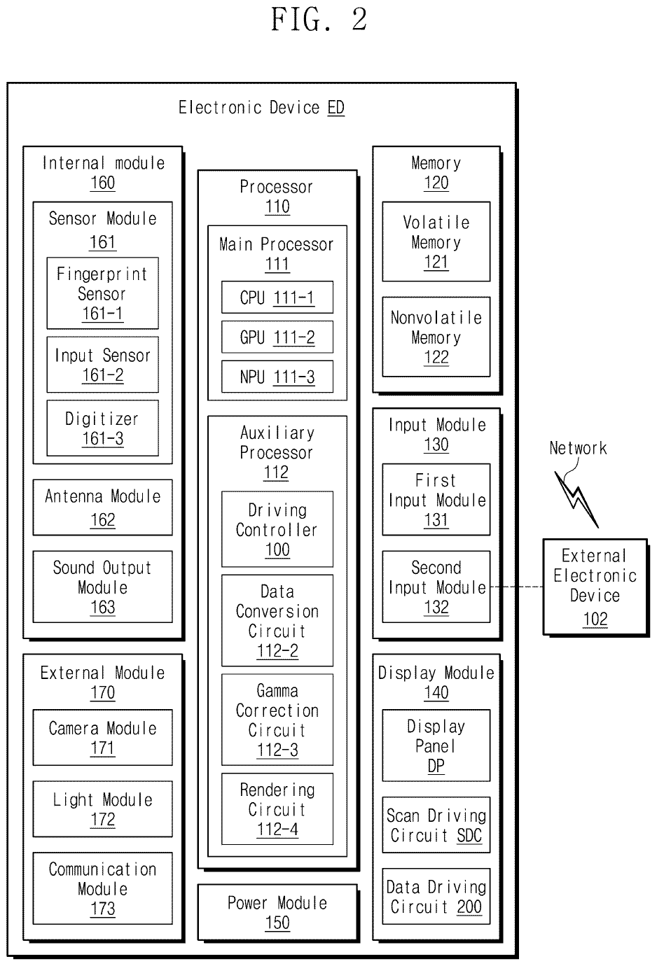

FIG. 2 is a block diagram of the electronic device ED according to an embodiment of the present disclosure.

Referring to FIG. 2, the electronic device ED may output various pieces of information through a display module 140 within an operating system. When a processor 110 executes an application stored in a memory 120, the display module 140 may provide application information to a user through the display panel DP.

The processor 110 may obtain an external input through an input module 130 or a sensor module 161 and execute an application corresponding to the external input. For example, when the user selects a camera icon displayed on the display panel DP, the processor 110 may obtain a user input through an input sensor 161-2 and activate a camera module 171. The processor 110 may transmit image data corresponding to a captured image obtained through the camera module 171 to the display module 140. The display module 140 may display an image corresponding to the captured image through the display panel DP.

According to an embodiment, when personal information authentication is executed in the display module 140, a fingerprint sensor 161-1 may acquire input fingerprint information as input data. The processor 110 may compare the input data acquired through the fingerprint sensor 161-1 with authentication data stored in the memory 120 and execute an application according to the comparison result. The display module 140 may display information executed according to a logic of the application through the display panel DP.

According to an embodiment, when a music streaming icon displayed on the display module 140 is selected, the processor 110 may obtain a user input through the input sensor 161-2 and activate a music streaming application stored in the memory 120. When a music playback command is input in the music streaming application, the processor 110 may activate an audio output module 163 to provide audio information corresponding to the music playback command to the user.

In the above, the operation of the electronic device ED is briefly described. Hereinafter, components of the electronic device ED will be described in detail. Some of the components of the electronic device ED described below may be integrated and provided as a single component, or one component may be provided after being separated into two or more components.

Referring to FIG. 2, the electronic device ED may communicate with an external electronic device 102 through a network (for example, a short-range wireless communication network or a long-range wireless communication network). According to an embodiment, the electronic device ED may include the processor 110, the memory 120, the input module 130, the display module 140, a power module 150, an internal module 160, and an external module 170. According to an embodiment, in the electronic device ED, at least one of the above-described components may be omitted or one or more other components may be added. According to an embodiment, some of the above-described components (for example, a sensor module 161, an antenna module 162, or an audio output module 163) may be integrated into another component (for example, the display module 140).

The processor 110 may execute software to control at least one other component (for example, a hardware or software component) of the electronic device ED connected to the processor 110 and may perform various data processing or computational operations. According to an embodiment, as at least a part of the data processing or computational operations, the processor 110 may store commands or data received from other components (for example, the input module 130, the sensor module 161, or a communication module 173) in a volatile memory 121, may process the commands or data stored in the volatile memory 121, and may store result data in a nonvolatile memory 122.

The processor 110 may include a main processor 111 and an auxiliary processor 112. The main processor 111 may include one or both of a central processing unit (CPU) 111-1 and an application processor (AP). The main processor 111 may further include any one or more of a graphics processing unit (GPU) 111-2, a communication processor (CP), and an image signal processor (ISP). The main processor 111 may further include a neural processing unit (NPU) 111-3. The NPU is a processor specialized in processing an artificial intelligence model, and the artificial intelligence model may be generated through machine learning. The artificial intelligence model may include a plurality of artificial neural network layers. The artificial neural network may be one of a deep neural network (DNN), a convolutional neural network (CNN), a recurrent neural network (RNN), a restricted boltzmann machine (RBM), a deep belief network (DBN), a bidirectional recurrent deep neural network (BRDNN), a deep Q-network, or a combination of two or more of the above, but is not limited to the above-described example. In addition to or as an alternative to a hardware structure, the artificial intelligence model may include a software structure. At least two of the above-described processing units and processors may be implemented as a single integrated component (for example, a single chip) or as separate components (for example, a plurality of chips).

The auxiliary processor 112 may include a driving controller 100. The driving controller 100 may include an interface conversion circuit and a timing control circuit. The driving controller 100 may receive an image signal from the main processor 111, convert a data format of the image signal to correspond to an interface specification with the display module 140, and output image data. The driving controller 100 may output various control signals required for driving the display module 140.

The auxiliary processor 112 may further include a data conversion circuit 112-2, a gamma correction circuit 112-3, a rendering circuit 112-4, and the like. The data conversion circuit 112-2 may receive the image data from the driving controller 100, compensate for the image data to display an image with a desired luminance based on characteristics of the electronic device ED, user settings, or the like, or convert the image data to reduce power consumption or to compensate for image retention. The gamma correction circuit 112-3 may convert the image data, a gamma reference voltage, or the like so that the image displayed on the electronic device ED has a desired gamma characteristic. The rendering circuit 112-4 may receive the image data from the driving controller 100 and render the image data taking into account a pixel arrangement or the like of the display panel DP applied to the electronic device ED. At least one of the data conversion circuit 112-2, the gamma correction circuit 112-3, and the rendering circuit 112-4 may be integrated into another component (for example, the main processor 111 or the driving controller 100). At least one of the data conversion circuit 112-2, the gamma correction circuit 112-3, and the rendering circuit 112-4 may be integrated into a data driving circuit 200, which is described later.

The memory 120 may store various data used by at least one component (for example, the processor 110 or the sensor module 161) of the electronic device ED and input or output data related to corresponding commands. The memory 120 may include at least one of the volatile memory 121 and the nonvolatile memory 122.

The input module 130 may receive commands or data to be used by a component (for example, the processor 110, the sensor module 161, or the audio output module 163) of the electronic device ED from an external source (for example, the user or the external electronic device 102) of the electronic device ED.

The input module 130 may include a first input module 131 receiving commands or data from the user and a second input module 132 receiving commands or data from the external electronic device 102. The first input module 131 may include a microphone, a mouse, a keyboard, a key (for example, a button), or a pen (for example, a passive pen or an active pen). The second input module 132 may support a designated protocol that enables connection to the external electronic device 102 via a wired or wireless connection. According to an embodiment, the second input module 132 may include a high definition multimedia interface (HDMI), a universal serial bus (USB) interface, an SD card interface, or an audio interface. The second input module 132 may include a connector capable of physically connecting to the external electronic device 102, for example, an HDMI connector, a USB connector, an SD card connector, or an audio connector (for example, a headphone connector).

The display module 140 may provide visual information to the user. The display module 140 may include the display panel DP, a scan driving circuit SDC, and the data driving circuit 200. The display module 140 may further include a window, a chassis, and a bracket to protect the display panel DP.

The display panel DP may include a liquid crystal display panel, an organic light emitting display panel, or an inorganic light emitting display panel, and a type of the display panel DP should not be particularly limited. The display panel DP may be a rigid type or a flexible type that may be rolled or folded. The display module 140 may further include a supporter, a bracket, a heat dissipation member, or the like that supports the display panel DP.

The scan driving circuit SDC may be mounted on the display panel DP as a driving chip. In addition, the scan driving circuit SDC may be integrated in the display panel DP. For example, the scan driving circuit SDC may include an amorphous silicon TFT gate driver circuit (ASG), a low temperature polycrystalline silicon (LTPS) TFT gate driver circuit, or an oxide semiconductor TFT gate driver circuit (OSG) built in the display panel DP. The scan driving circuit SDC may receive a control signal from the driving controller 100 and output scan signals to the display panel DP in response to the control signal.

The display panel DP may further include an emission driving circuit. The emission driving circuit may output an emission control signal to the display panel DP in response to a control signal received from the driving controller 100. The emission driving circuit may be formed separately from the scan driving circuit SDC or may be integrated into the scan driving circuit SDC.

The data driving circuit 200 may receive a control signal from the driving controller 100, convert image data into an analog voltage (for example, a data voltage) in response to the control signal, and then output the data voltages to the display panel DP. The data voltage provided to the pixels connected to a single data line may be switched continuously. According to an embodiment of the present disclosure, the data driving circuit 200 may control output timings of the data signals corresponding to two adjacent pixels differently and may provide a separately stored signal as an interpolation data voltage to prevent data peak occurrences caused by the overlap of data voltages. As a result, a display quality of the electronic device ED may be enhanced.

The data driving circuit 200 may be integrated into another component (for example, the driving controller 100). A function of the interface conversion circuit and the timing control circuit of the driving controller 100 described above may be integrated into the data driving circuit 200.

The display module 140 may further include the emission driving circuit, a voltage generator, and the like. The voltage generator may output various voltages required for driving the display panel DP.

The power module 150 may supply power to components of the electronic device ED. The power module 150 may include a battery that charges a power voltage. The battery may include a non-rechargeable primary cell, a rechargeable secondary cell, or fuel cell. The power module 150 may include a power management integrated circuit (PMIC). The PMIC may supply optimized power to each of the above-described modules and modules described later. The power module 150 may include a wireless power transmission/reception member electrically connected to the battery. The wireless power transmission/reception member may include a plurality of antenna radiators of a coil form.

The electronic device ED may further include the internal module 160 and the external module 170. The internal module 160 may include the sensor module 161, the antenna module 162, and the audio output module 163. The external module 170 may include the camera module 171, a light module 172, and the communication module 173.

The sensor module 161 may sense an input by a body of the user or an input by a pen of the first input module 131 and may generate an electrical signal or a data value corresponding to the input. The sensor module 161 may include at least one of the fingerprint sensor 161-1, the input sensor 161-2, and a digitizer 161-3.

The fingerprint sensor 161-1 may generate a data value corresponding to a fingerprint of the user. The fingerprint sensor 161-1 may include any one of an optical type fingerprint sensor or a capacitive type fingerprint sensor.

The input sensor 161-2 may generate a data value corresponding to coordinate information of the input by the body of the user or the input by the pen. The input sensor 161-2 may generate the data value based on the change in capacitance caused by the input. The input sensor 161-2 may sense an input by the passive pen or may transmit/receive data to and from the active pen.

The input sensor 161-2 may measure a biometric signal such as blood pressure, hydration levels, or body fat. For example, when the user touches a part of their body to a sensor layer or a sensing panel and remains still for a certain period, the input sensor 161-2 may sense the biometric signal based on changes in an electric field caused by the body part and output information desired by the user to the display module 140.

The digitizer 161-3 may generate a data value corresponding to coordinate information of the input by the pen. The digitizer 161-3 may generate the data value based on changes in an electromagnetic field caused by the input. The digitizer 161-3 may sense the input by the passive pen or may transmit/receive data to and from the active pen.

At least one of the fingerprint sensor 161-1, the input sensor 161-2, and the digitizer 161-3 may be implemented as a sensor layer formed on the display panel DP through a continuous process. The fingerprint sensor 161-1, the input sensor 161-2, and the digitizer 161-3 may be disposed above the display panel DP, or any one of the fingerprint sensor 161-1, the input sensor 161-2, and the digitizer 161-3, for example, the digitizer 161-3 may be disposed below the display panel DP.

At least two of the fingerprint sensor 161-1, the input sensor 161-2, and the digitizer 161-3 may be integrated into a single sensing panel through the same process. When at least two of the fingerprint sensor 161-1, the input sensor 161-2, and the digitizer 161-3 are integrated into one sensing panel, the sensing panel may be disposed between the display panel DP and the window disposed above the display panel DP. According to an embodiment, the sensing panel may be disposed on the window, and a position of the sensing panel should not be particularly limited.

At least one of the fingerprint sensor 161-1, the input sensor 161-2, and the digitizer 161-3 may be embedded in the display panel DP. That is, at least one of the fingerprint sensor 161-1, the input sensor 161-2, and the digitizer 161-3 may be simultaneously formed through a process of forming elements (for example, a light emitting element, a transistor, and the like) included in the display panel DP.

In addition, the sensor module 161 may generate an electrical signal or a data value corresponding to an internal state or an external state of the electronic device ED. The sensor module 161 may further include, for example, a gesture sensor, a gyro sensor, a barometric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The antenna module 162 may include one or more antennas to transmit a signal or power to an external source or to receive a signal or power from an external source. According to an embodiment, the communication module 173 may transmit a signal to an external electronic device or may receive a signal from an external electronic device through an antenna suitable for a communication method. An antenna pattern of the antenna module 162 may be integrated into one component (for example, the display panel DP) of the display module 140 or the input sensor 161-2.

The audio output module 163 is a device to output an audio signal to an outside of the electronic device ED and, for example, may include a speaker used for general purposes such as multimedia playback or voice recording playback and a receiver used exclusively to receive a phone call. According to an embodiment, the receiver may be formed integrally with or separately from the speaker. An audio output pattern of the audio output module 163 may be integrated into the display module 140.

The camera module 171 may capture a still image and a video. According to an embodiment, the camera module 171 may include one or more lenses, an image sensor, or an image signal processor. The camera module 171 may further include an infrared camera capable of detecting presence or absence of the user, a position of the user, a gaze of the user, and the like.

The light module 172 may provide light. The light module 172 may include a light emitting diode or a xenon lamp. The light module 172 may operate in conjunction with the camera module 171 or may operate independently.

The communication module 173 may support the establishment of a wired or wireless communication channel between the electronic device ED and the external electronic device 102 and the communication through the established communication channel. The communication module 173 may include one or both of a wireless communication module, such as a cellular communication module, a short-range wireless communication module, or a global navigation satellite system (GNSS) communication module, and a wired communication module, such as a local area network (LAN) communication module or a power line communication module. The communication module 173 may communicate with the external electronic device 102 through a short-range communication network such as Bluetooth, WiFi direct, or infrared data association (IrDA), or a long-range communication network such as a cellular network, the Internet, or a computer network (for example, LAN or WAN). The various types of communication modules 173 described above may be implemented as a single chip or as separate chips.

The input module 130, the sensor module 161, the camera module 171, and the like may be used in conjunction with the processor 110 to control an operation of the display module 140.

The processor 110 may output commands or data to the display module 140, the audio output module 163, the camera module 171, or the light module 172 based on input data received from the input module 130. For instance, the processor 110 may generate image data in response to the input data applied through the mouse, the active pen, or the like and output the image data to the display module 140, or may generate command data in response to the input data and output the command data to the camera module 171 or the light module 172. When no input data is received from the input module 130 for a certain period of time, the processor 110 may switch the operation mode of the electronic device ED to a low power mode or a sleep mode to reduce power consumed in the electronic device ED.

The processor 110 may output commands or data to the display module 140, the audio output module 163, the camera module 171, or the light module 172 based on sensing data received from the sensor module 161. For instance, the processor 110 may compare authentication data applied by the fingerprint sensor 161-1 with authentication data stored in the memory 120 and then execute an application according to a comparison result. The processor 110 may execute the command based on sensing data sensed by the input sensor 161-2 or the digitizer 161-3 or may output image data corresponding to the sensing data to the display module 140. When the sensor module 161 includes a temperature sensor, the processor 110 may receive temperature data measured by the sensor module 161 and further perform luminance correction or the like on the image data based on the temperature data.

The processor 110 may receive detected data regarding the presence or absence of the user, the position of the user, the gaze of the user, and the like, from the camera module 171. The processor 110 may further perform luminance correction or the like on the image data based on the detected data. For instance, when the processor 110 determines the presence or absence of the user through an input from the camera module 171, the processor 110 may output image data whose luminance is corrected through the data conversion circuit 112-2 or the gamma correction circuit 112-3 to the display module 140.

Among the above-described components, some components may be connected to each other through a communication method for peripheral devices, for example, a bus, general purpose input/output (GPIO), a serial peripheral interface (SPI), a mobile industry processor interface (MIPI), or an ultra-path interconnect (UPI) link to exchange a signal (for example, commands or data) with each other. The processor 110 may communicate with the display module 140 through a mutually agreed interface, for example, any one of the above-described communication methods, and the communication method is not limited to the above-described communication methods.

The electronic device ED according to various embodiments of the present disclosure may be applied to various types of devices. The electronic device ED may include, for example, at least one of a portable communication device (e.g., a smartphone), a computer device, a portable multimedia device, a portable medical device, a camera, a wearable device, and a home appliance device. The electronic device ED according to various embodiments of the present disclosure is not limited to the above-described devices.

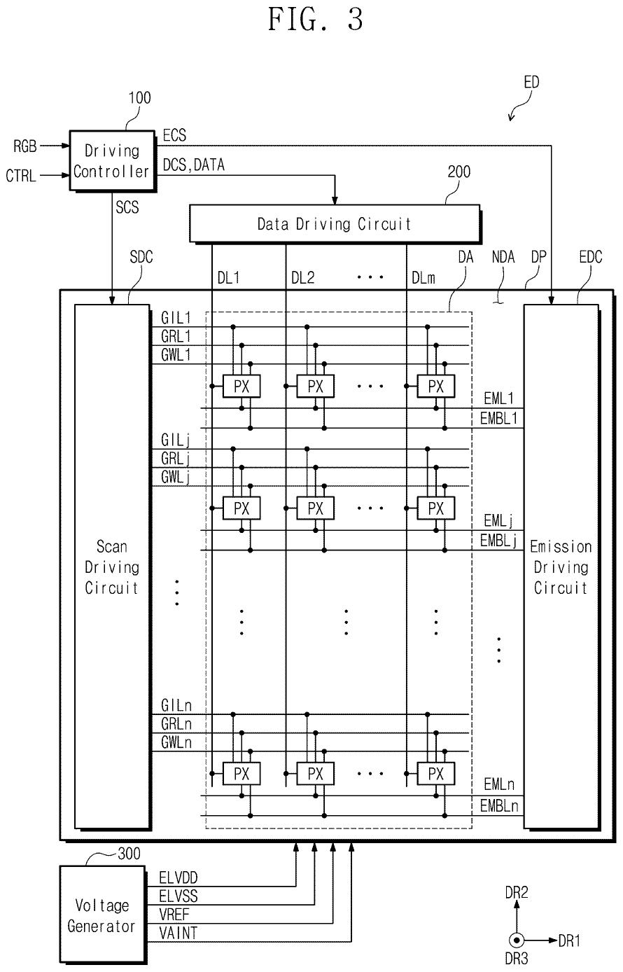

FIG. 3 is a block diagram of the electronic device ED according to an embodiment of the present disclosure.

Referring to FIG. 3, the electronic device ED may include the driving controller 100 (e.g., control circuit), the data driving circuit 200, a voltage generator 300, and the display panel DP.

The driving controller 100 may receive an input image signal RGB and a control signal CTRL. The driving controller 100 may convert a data format of the input image signal RGB to a data format appropriate to an interface between the data driving circuit 200 and the driving controller 100 to generate an output image signal DATA. The driving controller 100 may output a scan control signal SCS, a data control signal DCS, and an emission control signal ECS.

The data driving circuit 200 may receive the data control signal DCS and the output image signal DATA from the driving controller 100. The data driving circuit 200 may convert the output image signal DATA into data signals for output to a plurality of data lines DL1 to DLm. Each data signal may have a voltage level corresponding to a grayscale level of the output image signal DATA.

The data driving circuit 200 may be implemented in an integrated circuit (IC) and may be directly mounted on a selected portion of the display panel DP or may be electrically connected to the display panel DP after being mounted on a separate printed circuit board by a chip-on-film (COF) method. According to an embodiment, the data driving circuit 200 may be formed through the same process as a pixel circuit of each of the pixels PX on the display panel DP.

The voltage generator 300 may generate voltages for the operation of the display panel DP. In the present embodiment, the voltage generator 300 may generate a first driving voltage ELVDD, a second driving voltage ELVSS, a reference voltage VREF, and an initialization voltage VAINT. The first driving voltage ELVDD may be higher than the second driving voltage ELVSS.

The display panel DP may include the display area DA and the non-display area NDA. The display area DA may have a quadrangular shape, but is not limited thereto. The non-display area NDA may have a frame shape surrounding the display area DA.

The display panel DP may further include the scan driving circuit SDC and the emission driving circuit EDC. The pixels PX may be arranged in the display area DA, and the scan driving circuit SDC and the emission driving circuit EDC may be arranged in the non-display area NDA, but is not limited thereto. According to an embodiment, at least some of the pixels PX may overlap the scan driving circuit SDC and the emission driving circuit EDC. In this configuration, at least a portion of the scan driving circuit SDC and at least a portion of the emission driving circuit EDC may be arranged in the display area DA.

The display panel DP may include scan lines GIL1 to GILn, GRL1 to GRLn, and GWL1 to GWLn, emission control lines EML1 to EMLn and EMBL1 to EMBLn, the data lines DL1 to DLm, and the pixels PX. The scan lines GIL1 to GILn may be referred to as initialization scan lines GIL1 to GILn, the scan lines GRL1 to GRLn may be referred to as compensation scan lines GRL1 to GRLn, and the scan lines GWL1 to GWLn may be referred to as write scan lines GWL1 to GWLn. Each of “n” and “m” may be an integer number greater than or equal to 2.

The scan driving circuit SDC may receive the scan control signal SCS from the driving controller 100. The scan driving circuit SDC may output scan signals GI1 to GIn, GR1 to GRn, and GW1 to GWn to the scan lines GIL1 to GILn, GRL1 to GRLn, and GWL1 to GWLn in response to the scan control signal SCS. The emission driving circuit EDC may receive the emission control signal ECS from the driving controller 100. The emission driving circuit EDC may output emission signals EMI to EMn and EMB1 to EMBn to the emission control lines EML1 to EMLn and EMBL1 to EMBLn in response to the emission control signal ECS.

The scan driving circuit SDC may be disposed on a first side of the display panel DP. The scan lines GIL1 to GILn, GRL1 to GRLn, and GWL1 to GWLn may extend from the scan driving circuit SDC in the first direction DR1. The emission driving circuit EDC may be disposed on a second side of the display panel DP. The emission control lines EML1 to EMLn and EMBL1 to EMBLn may extend from the emission driving circuit EDC in a direction opposite to the first direction DR1. Each of the scan lines GIL1 to GILn, GRL1 to GRLn, and GWL1 to GWLn and each of the emission control lines EML1 to EMLn and EMBL1 to EMBLn may be arranged in the second direction DR2 and may be spaced apart from each other. The data lines DL1 to DLm may extend from the data driving circuit 200 in a direction opposite to the second direction DR2 and may be spaced apart from each other while being arranged in the first direction DR1.

As shown in FIG. 3, the scan driving circuit SDC and the emission driving circuit EDC may be arranged to face each other, and the pixels PX may be arranged between the scan driving circuit SDC and the emission driving circuit EDC, but is not limited thereto. As an example, both of the scan driving circuit SDC and the emission driving circuit EDC may be arranged adjacent to each other on one of the first side and the second side of the display panel DP. According to an embodiment, the scan driving circuit SDC and the emission driving circuit EDC may be implemented as a single circuit.

Each of the pixels PX may be electrically connected to three scan lines, two emission control lines, and one data line. For example, as shown in FIG. 3, the pixels PX arranged in a first row may be connected to the scan lines GIL1, GRL1, and GWL1 and the emission control lines EML1 and EMBL1. In addition, the pixels arranged in a j-th row may be connected to the scan lines GILj, GRLj, and GWLj and the emission control lines EMLj and EMBLj.

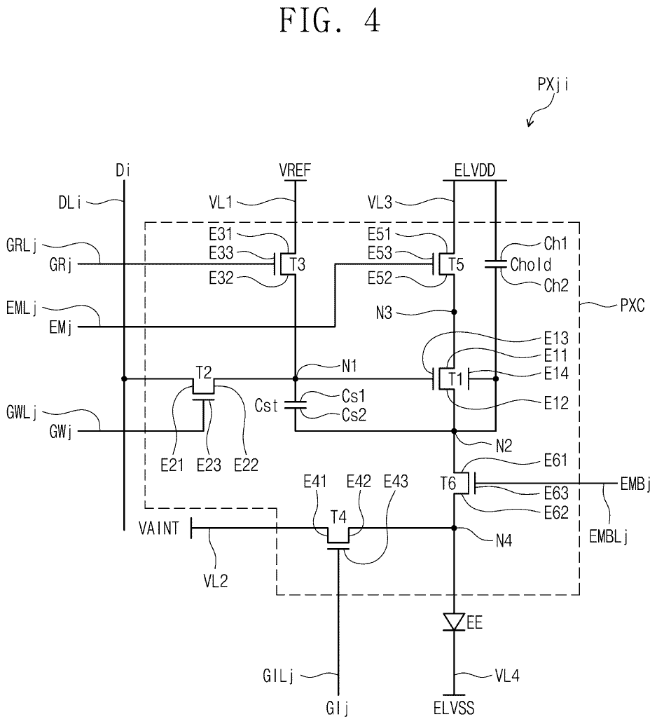

Each of the pixels PX may include a light emitting element EE (refer to FIG. 4) and a pixel circuit PXC (refer to FIG. 4) controlling the light emission of the light emitting element EE. The pixel circuit PXC may include one or more thin film transistors and one or more capacitors. The scan driving circuit SDC and the emission driving circuit EDC may include thin film transistors formed through the same process as the pixel circuit PXC.

Each of the pixels PX may receive the first driving voltage ELVDD, the second driving voltage ELVSS, the reference voltage VREF, and the initialization voltage VAINT from the voltage generator 300.

FIG. 4 is an equivalent circuit diagram of a pixel PXji according to an embodiment of the present disclosure.

Referring to FIGS. 3 and 4, the equivalent circuit diagram of the pixel PXji, which is connected to an i-th data line DLi among the data lines DL1 to DLm, j-th scan lines GILj, GRLj, and GWLj among the scan lines GIL1 to GILn, GRL1 to GRLn, and GWL1 to GWLn, and j-th emission control lines EMLj and EMBLj among the emission control lines EML1 to EMLn and EMBL1 to EMBLn, is shown as a representative example. Each of the pixels PX shown in FIG. 3 may have the same circuit configuration as the equivalent circuit diagram of the pixel PXji shown in FIG. 4.

The pixel circuit PXC may include first, second, third, fourth, fifth, and sixth transistors T1, T2, T3, T4, T5, and T6, a first capacitor Cst, and a second capacitor Chold. The first capacitor Cst and the second capacitor Chold may be referred to as a transmission capacitor Cst and a hold capacitor Chold, respectively. The pixel PXji shown in FIG. 4 is merely an example, and the circuit configuration of the pixel PXji may be changed.

Each of the first, second, third, fourth, fifth, and sixth transistors T1, T2, T3, T4, T5, and T6 may be an N-type transistor having an oxide semiconductor layer. The first transistor T1 may be referred to as a driving transistor, the second transistor T2 may be referred to as a switching transistor, the third transistor T3 may be referred to as a compensation transistor, the fourth transistor T4 may be referred to as an initialization transistor, the fifth transistor T5 may be referred to as a first emission control transistor, and the sixth transistor T6 may be referred to as a second emission control transistor.

The scan lines GILj, GRLj, and GWLj may transmit scan signals GIj, GRj, and GWj, respectively, and the emission control lines EMLj and EMBLj may transmit emission signals EMj and EMBj, respectively. The data line DLi may transmit a data signal Di. The data signal Di may have a voltage level corresponding to the input image signal RGB input into the electronic device ED.

First, second, third, and fourth voltage lines VL1, VL2, VL3, and VL4 may transmit the reference voltage VREF, the initialization voltage VAINT, the first driving voltage ELVDD, and the second driving voltage ELVSS to the pixel PXji, respectively.

The first capacitor Cst may be connected between a first node N1 and a second node N2. A first opposite electrode Cs1 of the first capacitor Cst may be connected to the first node N1, and a second opposite electrode Cs2 of the first capacitor Cst may be connected to the second node N2.

The first transistor T1 may be connected between the second node N2 and a third node N3. The first transistor T1 may include a first electrode E11 connected to the third node N3, a second electrode E12 connected to the second node N2, a first gate electrode E13 connected to the first node N1, and a second gate electrode E14 connected to the second node N2. The first gate electrode E13 may be referred to as a gate electrode, and the second gate electrode E14 may be referred to as a back gate electrode. The first electrode E11 of the first transistor T1 may be electrically connected to the third voltage line VL3 through the fifth transistor T5.

The second transistor T2 (or a test transistor) may be connected between the data line DLi and the first node N1. The second transistor T2 may include a first electrode E21 connected to the data line DLi, a second electrode E22 connected to the first node N1, and a gate electrode E23 connected to the scan line GWLj. The second transistor T2 may be turned on in response to the scan signal GWj received through the scan line GWLj and may transmit the data signal Di received through the data line DLi to the first node N1.

The third transistor T3 may be connected between the first voltage line VL1 and the first node N1. The third transistor T3 may include a first electrode E31 connected to the first voltage line (or a reference voltage line) VL1, a second electrode E32 connected to the first node N1, and a gate electrode E33 connected to the scan line GRLj. The third transistor T3 may be turned on in response to the scan signal GRj received through the scan line GRLj and may transmit the reference voltage VREF to the first node N1.

The fourth transistor T4 may be connected between the second voltage line VL2 and a fourth node N4. The fourth transistor T4 may include a first electrode E41 connected to the second voltage line (or an initialization voltage line) VL2, a second electrode E42 connected to the fourth node N4, and a gate electrode E43 connected to the scan line GILj. The fourth transistor T4 may transmit the initialization voltage VAINT received through the second voltage line VL2 to the fourth node N4 in response to the scan signal GIj received through the scan line GILj.

The fifth transistor T5 may be connected between the third voltage line VL3 and the third node N3. The fifth transistor T5 may include a first electrode E51 connected to the third voltage line VL3, a second electrode E52 connected to the first electrode E11 of the first transistor T1, and a gate electrode E53 connected to the emission control line EMLj. The fifth transistor T5 may be turned on in response to the emission signal EMj received through the emission control line EMLj and may electrically connect the third voltage line VL3 to the first electrode E11 of the first transistor T1.

The sixth transistor T6 may be connected between the second node N2 and the fourth node N4. The sixth transistor T6 may include a first electrode E61 connected to the second node N2, a second electrode E62 connected to the fourth node N4, and a gate electrode E63 connected to the emission control line EMBLj. The sixth transistor T6 may be turned on in response to the emission signal EMBj and may electrically connect the second node N2 and the fourth node N4.

The second capacitor Chold may be connected between the third voltage line VL3 and the back gate electrode E14 of the first transistor T1. A first hold opposite electrode Ch1 of the second capacitor Chold may be connected to the third voltage line VL3, and a second hold opposite electrode Ch2 of the second capacitor Chold may be connected to the back gate electrode E14 of the first transistor T1. According to an embodiment of the present disclosure, the second hold opposite electrode Ch2 of the second capacitor Chold may be electrically connected to the second node N2. In this configuration, the back gate electrode E14 of the first transistor T1 may be electrically connected to the second node N2.

According to an embodiment of the present disclosure, the second capacitor Chold is omitted. For example, when the second capacitor Chold is omitted, the first transistor T1 may be replaced with another that does not include the back gate electrode E14.

The light emitting element EE may include an anode connected to the second electrode E62 of the sixth transistor T6 or the fourth node N4 and a cathode connected to the fourth voltage line VL4.

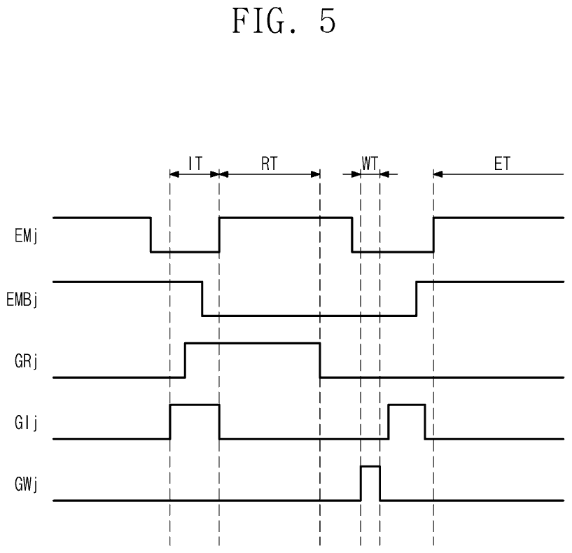

FIG. 5 is a timing diagram illustrating an operation of the pixel circuit PXC according to an embodiment of the present disclosure.

FIG. 5 illustrates a waveform of each of the emission signals EMj and EMBj and the scan signals GIj, GRj, and GWj corresponding to each period. The emission signals EMj and EMBj may be referred to as a first emission signal EMj and a second emission signal EMBj, respectively, and the scan signals GIj, GRj, and GWj may be referred to as an initialization scan signal GIj, a compensation scan signal GRj, and a write scan signal GWj, respectively.

Referring to FIGS. 4 and 5, the pixel circuit PXC may be configured to operate in accordance with an initialization period IT, a compensation period RT, a write period WT, and an emission period ET. In an embodiment, the periods of the initialization period IT, the compensation period RT, the write period WT, and the emission period ET do not overlap.

In the initialization period IT, the initialization scan signal GIj may have a logic high level. The fourth transistor T4 may be turned on in response to the initialization scan signal GIj. The initialization voltage VAINT may be applied to the fourth node N4 through the fourth transistor T4. In addition, the initialization voltage VAINT may be applied to the second node N2 through the sixth transistor T6 that is turned on in response to the second emission signal EMBj. Accordingly, a voltage level of the second node N2 and a voltage level of the fourth node N4 may be initialized in the initialization period IT.

In the compensation period RT, the compensation scan signal GRj and the first emission signal EMj may have a logic high level. The third transistor T3 may be turned on in response to the compensation scan signal GRj, and the fifth transistor T5 may be turned on in response to the first emission signal EMj. The reference voltage VREF may be applied to the first node N1 by the turned-on third transistor T3, and the first electrode E11 of the first transistor T1 may be connected to the third voltage line VL3 by the turned-on fifth transistor T5. In this case, a certain amount of charge may be stored in the first capacitor Cst, and thus, a threshold voltage of the first transistor T1 may be compensated.

In the write period WT, the write scan signal GWj may have a logic high level. The second transistor T2 may be turned on in response to the write scan signal GWj. The data signal Di may be applied to the gate electrode E13 of the first transistor T1 by the turned-on second transistor T2.

Then, in the emission period ET, the first emission signal EMj and the second emission signal EMBj may have a logic high level. The fifth transistor T5 and the sixth transistor T6 may be turned on in response to the first emission signal EMj and the second emission signal EMBj, respectively. A current path may be formed between the third voltage line VL3 and the light emitting element EE through the fifth transistor T5 and the sixth transistor T6. Then, a driving current Id, generated by the voltage difference between the gate electrode E13 of the first transistor T1 and the first driving voltage ELVDD may flow the light emitting element EE, causing the light emitting element EE to emit light.

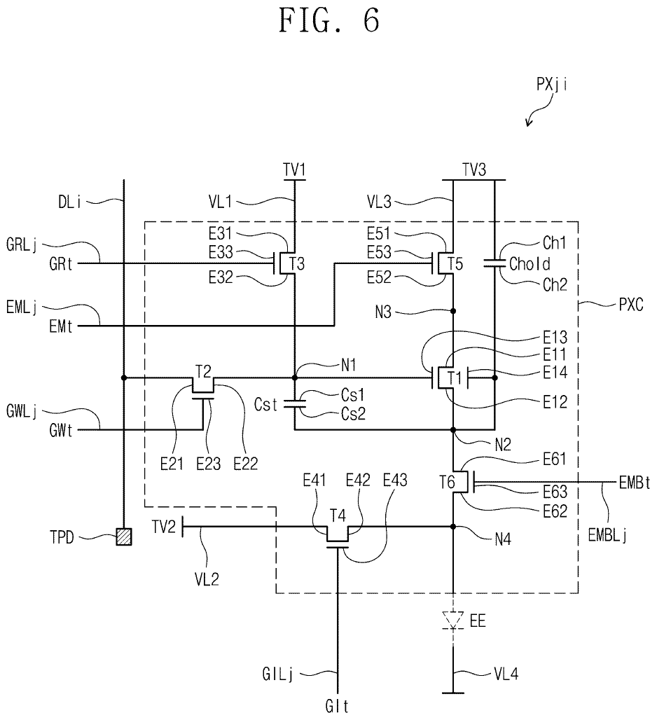

FIG. 6 is a circuit diagram illustrating an operation of testing the pixel circuit PXC according to an embodiment of the present disclosure.

Referring to FIGS. 3, 4, and 6, a method of manufacturing the display panel DP may include forming the pixel circuit PXC including the first, second, third, fourth, fifth, and sixth transistors T1, T2, T3, T4, T5, and T6, the first capacitor Cst, and the second capacitor Chold, testing the pixel circuit PXC, and forming the light emitting element EE connected to the pixel circuit PXC.

The testing operation may be performed to test whether the first transistor T1 is operating normally by measuring a current flowing through the first node N1 connected to the gate electrode E13 of the first transistor T1. The operation of testing the pixel circuit PXC may be performed during the process of forming of the pixel PXji. As an example, the operation of testing the pixel circuit PXC may be performed before the formation of the light emitting element EE. In FIG. 6, the light emitting element EE is shown as a dotted line to illustrate the operation of testing the pixel circuit PXC before the formation of the light emitting element EE.

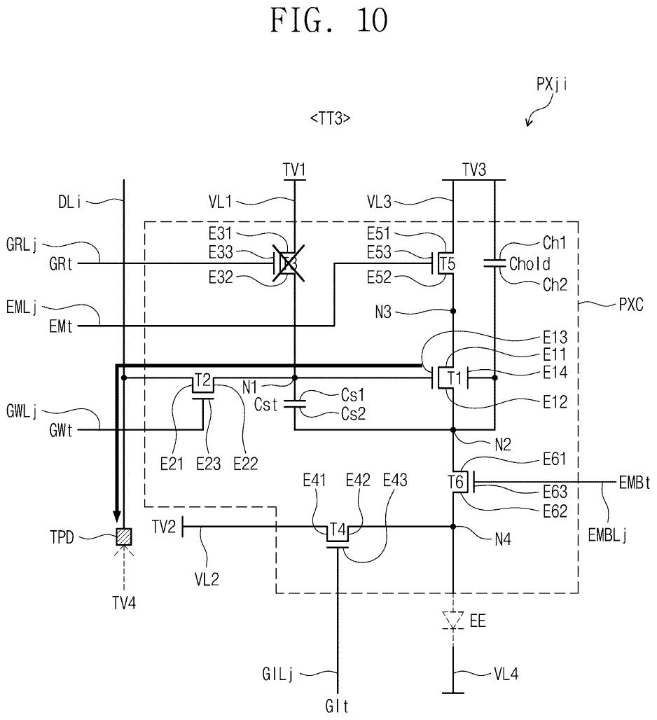

In an embodiment, the operation of testing the pixel circuit PXC includes applying a first test voltage TV1 to the first voltage line VL1, applying a second test voltage TV2 to the second voltage line VL2, applying a third test voltage TV3 to the third voltage line VL3, and applying a bias voltage TV4 (refer to FIG. 10) to the data line DLi. The bias voltage TV4 may be an analog voltage. A test circuit may apply the test voltages TV1, TV2, TV3, and TV4 and then read a resulting test current from a test pad TDD.

When it is determined from the test current that the first transistor T1 is defective, a repair process may be applied to the pixel circuit PXC. If repair is not possible, the manufacturing process of the display panel may be terminated before proceeding to subsequent steps. Upon confirming through the testing operation that the pixel circuit PXC functions normally, the manufacturing process proceeds for form the light emitting element EE. For example, the test results could be processed by a control circuit, which communicates with the manufacturing equipment to either continue with the formation of the light emitting element EE or stop the process. The waste of manufacturing time and cost for the display panel DP may be reduced. Detailed explanation of the operation of testing the pixel circuit PXC will be described below.

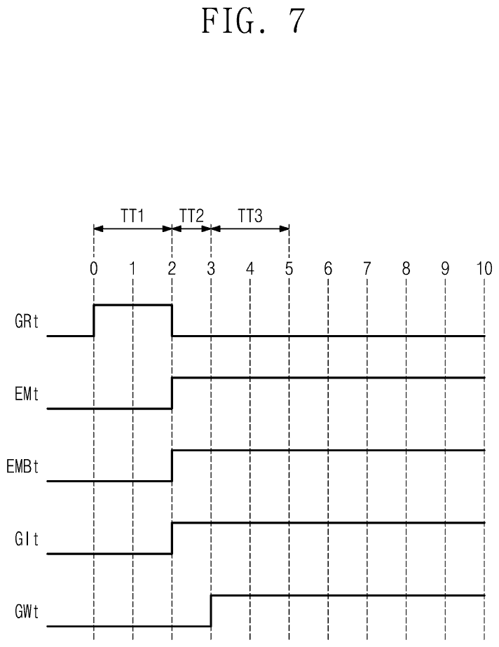

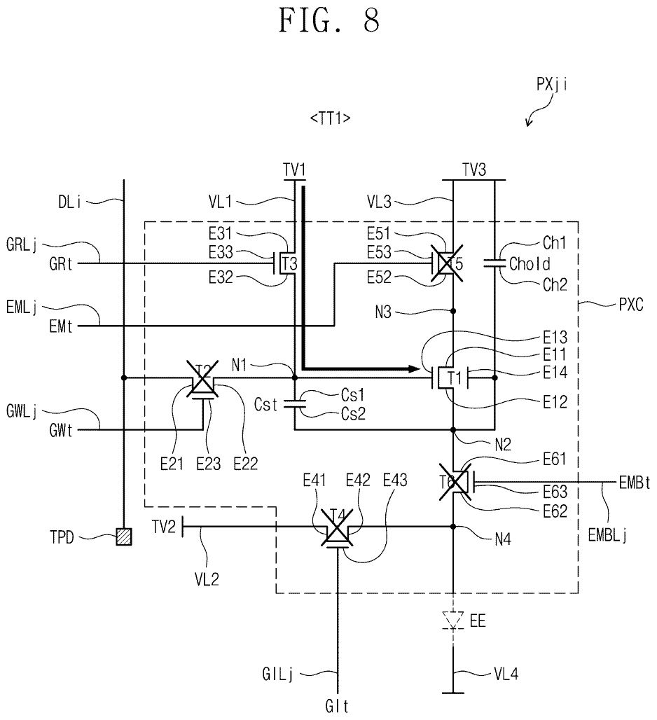

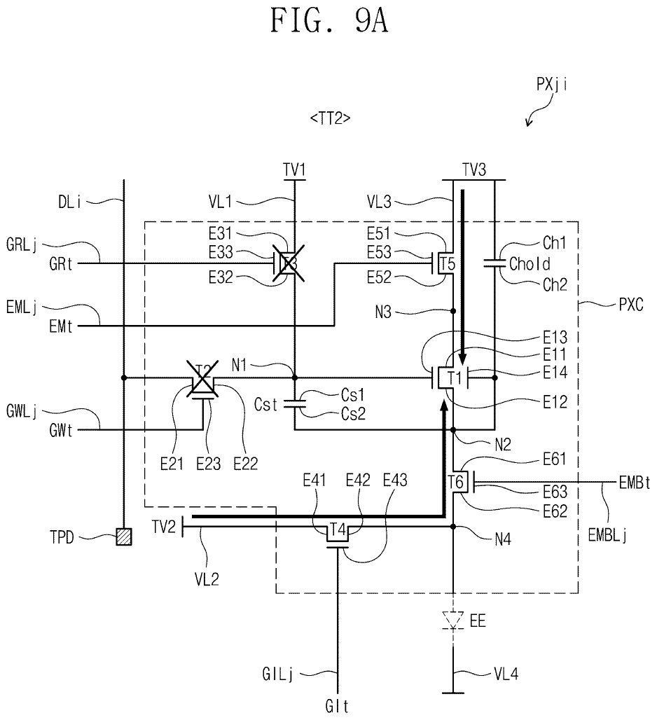

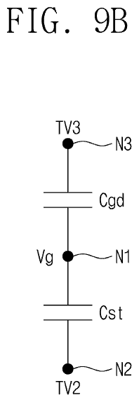

FIG. 7 is a timing diagram illustrating the operation of testing the pixel circuit PXC according to an embodiment of the present disclosure. FIG. 8 is a view illustrating the operation of testing the pixel circuit PXC in a first period TT1 shown in FIG. 7. FIG. 9A is a view illustrating the operation of testing the pixel circuit PXC in a second period TT2 shown in FIG. 7. FIG. 9B is a view illustrating the operation of testing the pixel circuit PXC in the second period TT2 shown in FIG. 7. FIG. 10 is a view illustrating the operation of testing the pixel circuit PXC in a third period TT3 shown in FIG. 7.

Hereinafter, emission signals EMt and EMBt shown in FIG. 7 may be referred to as a first emission signal EMt and a second emission signal EMBt, respectively, and scan signals GIt, GRt, and GWt may be referred to as a first scan signal GIt, a second scan signal GRt, and a third scan signal GWt.

Referring to FIGS. 7 and 8, during the first period TT1, the first test voltage TV1 may be applied to the first node N1 connected to the gate electrode E13 of the first transistor T1.

According to an embodiment of the present disclosure, during the first period TT1, the second scan signal GRt may have a logic high level, while the first emission signal EMt, the second emission signal EMBt, the first scan signal GIt, and the third scan signal GWt may all remain at a logic low level. Accordingly, in the applying of the first test voltage TV1, the third transistor T3 may be turned on, and the second transistor T2, the fourth transistor T4, the fifth transistor T5, and the sixth transistor T6 may be turned off.

The first test voltage TV1 applied through the first voltage line VL1 may be applied to the first node N1 through the turned-on third transistor T3. That is, the first test voltage TV1 may be applied to the gate electrode E13 of the first transistor T1 connected to the first node N1.

According to an embodiment, a voltage level of the first test voltage TV1 may vary. As an example, the voltage level of the first test voltage TV1 may vary within a selected range. The selected range may range from about-10V to about 10V, but is not limited thereto. As an example, the voltage level of the first test voltage TV1 may vary within a wider or narrower range than the range described above.

The selected range may be a dynamic range of the voltage applied to the first transistor T1. As the voltage level of the first test voltage TV1 varies, the first transistor T1 may be tested for each period within the dynamic range. As an example, by measuring the current at the first node N1 while varying the voltage level of the first test voltage TV1, it is possible to detect color deviation defects and assess image sticking performance. The image sticking figure of merit may may serve as an index to evaluate the extent of image retention in the display panel.

Referring to FIGS. 7 and 9A, during the second period TT2, a current path is established between the third node N3 and the second node N2. This may be achieved by applying the second test voltage TV2 to the second node N2 and the third test voltage TV3 to the third node N3, thereby enabling current flow between these nodes for testing purposes. In an embodiment, the third test voltage TV3 is different from the second test voltage TV2.

During the second period TT2, the first emission signal EMt, the second emission signal EMBt, and the first scan signal GIt may have a logic high level, while the second scan signal GRt and the third scan signal GWt may have a logic low level. Accordingly, in the applying of the second test voltage TV2, the fourth transistor T4 and the sixth transistor T6 may be turned on, and the second transistor T2 and the third transistor T3 may be turned off. In addition, in the applying of the third test voltage TV3, the fifth transistor T5 may be turned on, and the second transistor T2 and the third transistor T3 may be turned off.

The second test voltage TV2 provided through the second voltage line VL2 may be applied to the second node N2 through the fourth node N4 when the fourth transistor T4 and the sixth transistor T6 are turned on. The third test voltage TV3 provided through the third voltage line VL3 may be applied to the third node N3 through the turned-on fifth transistor T5. That is, the second test voltage TV2 may be applied to the second electrode E12 of the first transistor T1 connected to the second node N2, and the third test voltage TV3 may be applied to the first electrode E11 of the first transistor T1 connected to the third node N3.

Due to the first test voltage TV1 applied to the gate electrode E13 of the first transistor T1, the second test voltage TV2 applied to the second electrode E12 of the first transistor T1, and the third test voltage TV3 applied to the first electrode E11 of the first transistor T1, a current path may be formed between the first electrode E11 of the first transistor T1 and the second electrode E12 of the first transistor T1.

In an embodiment, the second test voltage TV2 has a voltage level lower than a voltage level of the third test voltage TV3. As an example, the voltage level of the second test voltage TV2 may be about −2.1V, and the voltage level of the third test voltage TV3 may be about 3V, but is not limited thereto.

Referring to FIGS. 7, 9A, and 9B, during the second period TT2, a parasitic capacitor Cgd may be formed between the first node N1 connected to the gate electrode E13 of the first transistor T1 and the third node N3 to which the third test voltage TV3 is applied.

In the forming of the current path, a voltage Vg at the first node N1 may be coupled to the second node N2 via the first capacitor Cst and coupled to the third node N3 via the parasitic capacitance between gate and drain, denoted as Cgd, as shown in Equation 1 below.

$$Δ Vg = \frac{Cst Δ TV 2 + Cgd Δ TV 3}{Cst + Cgd} \qquad [ Equation 1 ]$$

The voltage Vg of the first node N1 may vary due to the first capacitor Cst and the parasitic capacitance Cgd. In this configuration, the variation in the voltage Vg of the first node N1 may differ depending on a capacity and compensation time of the first capacitor Cst and the parasitic capacitance Cgd. Accordingly, it is possible to determine whether the first transistor T1 is operating normally or abnormally by measuring the voltage Vg of the first node N1 using the first test voltage TV1, the second test voltage TV2, and the third test voltage TV3.

Referring to FIGS. 7 and 10, during the third period TT3, the current flowing through the first node N1 may be measured via the data line DLi.

In the third period TT3, the first emission signal EMt, the second emission signal EMBt, the first scan signal GIt, and the third scan signal GWt may have a logic high level, while the second scan signal GRt may have a logic low level. Accordingly, in the operation of measuring the current, the second transistor T2, the fourth transistor T4, the fifth transistor T5, and the sixth transistor T6 may be turned on, while the third transistor T3 may be turned off.

FIG. 7 shows the timing diagram in which the first period TT1 has a duration of two horizontal cycles, the second period TT2 has a duration of one horizontal cycle, and the third period TT3 has a duration of two horizontal cycles, but is not limited thereto. The horizontal cycle may refer to a horizontal scanning period (or horizontal sync period) of the display panel DP, which is the time taken to scan one horizontal line (or row) of pixels. A cycle of each of the first period TT1, the second period TT2, and the third period TT3 may be changed as long as the first period TT1, the second period TT2, and the third period TT3 proceed sequentially.

According to an embodiment, the operation of measuring the current may include turning on the second transistor T2, applying the bias voltage TV4 to the data line DLi after turning on the second transistor T2, and measuring the current flowing through the first node N1 coupled to the second node N2. In this case, the current is discharged from the first node N1 through the second transistor T2 to the data line DLi, and is measured at a test pad (TPD) connected to the data line DLi using external measuring equipment.

After the second transistor T2 is turned on and the bias voltage TV4 is applied to the data line DLi, the current flowing through the first node N1 may be supplied to the test pad TPD through the second transistor T2 and the data line DLi.

The bias voltage TV4 may have a voltage level lower than the voltage level of the first node N1. As an example, the bias voltage TV4 may be 0V, but is not limited thereto. Accordingly, the current flowing through the first node N1, which is coupled to the second node N2, may flow to the test pad TPD via the data line DLi and may be measured using external equipment.

When the current measured by the test pad TPD is at a level substantially identical to an ideal current, it is determined that the first transistor T1 is operating normally. When the current measured by the test pad TPD is an abnormal current that is different from the ideal current, it is determined that the first transistor T1 is operating abnormally, and a subsequent process (e.g., a repair process) may be performed.

When it is determined that the pixel circuit PXC is defective through the testing operation, the pixel circuit PXC may undergo a repair process. If repair is not possible, the manufacturing process of the display panel may be terminated without proceeding to next process. If the pixel circuit PXC is determined to be functioning normally through the testing operation, the light emitting element EE may then be formed through subsequent processes. Testing the pixel circuit PXC in this manner can help to reduce manufacturing time and costs associated with the display panel DP (refer to FIG. 3).

During the operation of testing the pixel circuit PXC, a measuring instrument (or device) capable of measuring both the capacitance of a capacitor and low current may be used. The measuring instrument may be configured with an ammeter and a voltmeter connected in series. In addition, a flexible circuit film that prevents signal lines from transmitting direct current (DC) and alternating current (AC) signals from overlapping may be used to measure the low current. As an example, the signal lines may be electrically connected using the flexible circuit film so that the DC and AC signals do not interfere with one another.

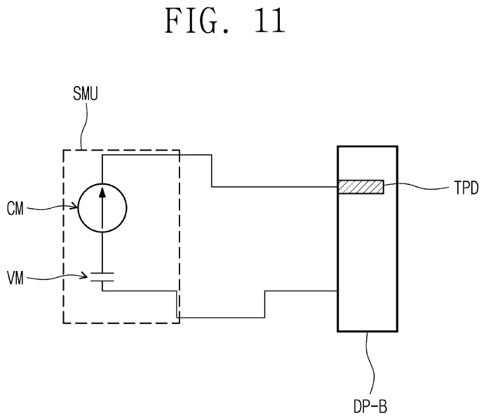

FIG. 11 is a block diagram schematically illustrating a measuring equipment SMU used for the testing operation according to an embodiment of the present disclosure.

Referring to FIGS. 10 and 11, the measuring equipment SMU may measure the current flowing through the first node N1 using the test pad TPD. The current flowing through the first node N1 may be a low current less than one picoampere (pA).

The measuring equipment SMU may be a source measure unit (SMU) in which a current source CM and a voltage source VM are connected in series. A power line cycle (PLC) may be applied to the measuring equipment SMU. For example, a measurement integration time corresponding to one or more power line cycles (PLCs) may be applied to the measuring equipment SMU to reduce power line noise and enhance measurement accuracy. In addition, the measuring equipment SMU may measure not only current but also charge. The measuring equipment SMU may have an AC/DC insulation resistance of at least about 1 gigohm (1 GΩ) to measure the low current, but is not limited thereto. The measuring equipment SMU may include a printed circuit board designed such that the AC and DC signals do not interfere with each other.

The measuring equipment SMU may measure currents flowing through the first node N1 from multiple pixel circuits PXC included in a preliminary display panel DP-B. In this case, the preliminary display panel DP-B may be in a state after the pixel circuits PXC are formed and before the light emitting elements EE are formed. The dispersion of the threshold voltage of the first transistors T1 of the pixel circuits PXC may be checked based on the measured currents. In addition, operating characteristics of a transistor, such as transfer curve, hysteresis characteristics, leakage current, etc., may be measured using the measuring equipment SMU.

The measuring equipment SMU may be used to detect temperature-dependent characteristics. As an example, by measuring the current of the preliminary display panel DP-B at various temperatures, luminance sensitivity samples and color coordinate sensitivity samples corresponding to each temperature may be obtained.

According to the above, non-uniformities resulting from the dispersion of the threshold voltage of the first transistors T1 may be detected early during the manufacturing process of the display panel DP (refer to FIG. 3), and thus, a defect rate may be reduced and a manufacturing yield may be enhanced. In addition, the image quality of the display panel DP (refer to FIG. 3) may be enhanced by designing a correction algorithm based on luminance sensitivity samples and other color coordinate sensitivity samples obtained at various temperatures.

Although various embodiments of the present disclosure have been described, it is understood that the present disclosure is not limited to these embodiments but various changes and modifications can be made by one ordinary skilled in the art within the spirit and scope of the present disclosure as hereinafter claimed. Therefore, the disclosed subject matter is not limited to any single embodiment described herein.

What is claimed is:

1. A method of inspecting a display panel, comprising:
testing a pixel circuit comprising a first capacitor connected between a first node and a second node, a first transistor comprising a first electrode connected to a third node, a gate electrode connected to the first node, and a second electrode connected to the second node, and a second transistor connected between the first node and a data line, the testing of the pixel circuit comprising:
applying a first test voltage to the first node;
forming a current path between the third node and the second node; and
measuring a current flowing through the first node via the data line.

2. The method of claim 1, wherein a voltage at the first node is coupled to the second node by the first capacitor in the forming of the current path.

3. The method of claim 2, wherein the measuring of the current comprises:
turning on the second transistor; and
measuring the current flowing through the first node coupled to the second node.

4. The method of claim 3, wherein the measuring of the current further comprises applying a bias voltage to the data line after the second transistor is turned on.

5. The method of claim 1, wherein the forming of the current path comprises:
applying a second test voltage to the second node; and
applying a third test voltage different from the second test voltage to the third node.

6. The method of claim 5, wherein a voltage level of the second test voltage is lower than a voltage level of the third test voltage.

7. The method of claim 5, wherein the pixel circuit further comprises:
a third transistor connected between a first voltage line and the first node, the first voltage line transmitting the first test voltage;
a fourth transistor connected between a second voltage line and a fourth node, the second voltage line transmitting the second test voltage; and
a fifth transistor connected between a third voltage line and the third node, the third voltage line transmitting the third test voltage.

8. The method of claim 7, wherein the third transistor is turned on in the applying of the first test voltage, and the second transistor, the fourth transistor, and the fifth transistor are turned off in the applying of the first test voltage.

9. The method of claim 7, wherein the fourth transistor is turned on in the applying of the second test voltage, and the second transistor and the third transistor are turned off in the applying of the second test voltage.

10. The method of claim 7, wherein the fifth transistor is turned on in the applying of the third test voltage, and the second transistor and the third transistor are turned off in the applying of the third test voltage.

11. The method of claim 7, wherein the pixel circuit further comprises a sixth transistor connected between the second node and the fourth node, the fourth transistor and the sixth transistor are turned on in the applying of the second test voltage, and the second transistor and the third transistor are turned off in the applying of the second test voltage.

12. The method of claim 5, wherein the pixel circuit further comprises a second capacitor connected between a third voltage line and a back gate electrode of the first transistor, the third voltage line providing the third test voltage.

13. The method of claim 12, wherein the back gate electrode of the first transistor is connected to the second node.

14. The method of claim 1, wherein a voltage level of the first test voltage varies.

15. A method of manufacturing an electronic device, comprising:
forming a pixel circuit comprising a plurality of transistors and a plurality of capacitors;
testing the pixel circuit; and
forming a light emitting element connected to the pixel circuit, the pixel circuit comprising:
a first capacitor connected between a first node and a second node;
a first transistor comprising a first electrode connected to a third node, a gate electrode connected to the first node, a second electrode connected to the second node, and a back gate electrode;
a second transistor connected between the first node and a data line;
a third transistor connected between a first voltage line and the first node;
a fourth transistor connected between a second voltage line and a fourth node;
a fifth transistor connected between a third voltage line and the third node;
a sixth transistor connected between the second node and the fourth node; and
a second capacitor connected between the third voltage line and the back gate electrode of the first transistor, the testing of the pixel circuit comprising:
applying a first test voltage to the first node;
forming a current path between the third node and the second node; and
measuring a current flowing through the first node via the data line.

16. The method of claim 15, wherein a voltage at the first node is coupled to the second node by the first capacitor in the forming of the current path.

17. The method of claim 16, wherein the measuring of the current comprises:
turning on the second transistor;
applying a bias voltage to the data line; and
measuring the current flowing through the first node coupled to the second node.

18. The method of claim 15, wherein the forming of the current path comprises:
applying a second test voltage to the second node; and
applying a third test voltage different from the second test voltage to the third node, and a voltage level of the second test voltage is lower than a voltage level of the third test voltage.

19. The method of claim 18, wherein the third transistor is turned on in the applying of the first test voltage, the second transistor, the fourth transistor, and the fifth transistor are turned off in the applying of the first test voltage, the fourth transistor and the sixth transistor are turned on in the applying of the second test voltage, the second transistor and the third transistor are turned off in the applying of the second test voltage, the fifth transistor is turned on in the applying of the third test voltage, and the second transistor and the third transistor are turned off in the applying of the third test voltage.

20. A method of manufacturing a display panel, comprising:
forming a pixel circuit comprising:
a first transistor comprising a gate electrode connected to a first node, a first electrode connected to a third node, and a second electrode connected to a second node;
a first capacitor connected between the first node and the second node; and
a second transistor connected between the first node and a data line;
applying a first test voltage to the first node;
applying a second test voltage to the second node;
applying a third test voltage, different from the second test voltage, to the third node, to form a current path through the first transistor;
turning on the second transistor and applying a bias voltage to the data line;
measuring a current flowing from the first node through the second transistor to the data line; and
forming a light emitting element electrically connected to the pixel circuit when the measured current indicates the pixel circuit is functioning normally.
